(19) United States
(12) Patent Application Publication
(10) Pub. No.: US 2018/0247835 A1
(43) Pub. Date: Aug. 30, 2018

(54) NOZZLE, SUBSTRATE TREATING APPARATUS INCLUDING THE SAME, AND SUBSTRATE TREATING METHOD

(71) Applicants: SEMES CO., LTD., Chungcheongnam-do (KR); SNU R&DB FOUNDATION, Seoul (KR)

(72) Inventors: SOO YEON LEE, Chungcheongnam-do (KR); HO-YOUNG KIM, Seoul (KR); SEUNGHO KIM, Gyeonggi-do (KR); JAE HONG LEE, Seoul (KR); JOONOH KIM, Busan (KR); JINKYU KIM, Busan (KR); BYUNG MAN KANG, Chungcheongnam-do (KR); IN IL JUNG, Chungcheongnam-do (KR)

(21) Appl. No.: 15/769,367

(22) PCT Filed: Oct. 20, 2016
(86) PCT No.: PCT/KR2016/011816

§ 371 Date: Apr. 19, 2018

(30) Foreign Application Priority Data
Oct. 29, 2015 (KR) 10-2015-0150921

(51) Int. Cl. H01L 21/67; H01L 21/02; B08B 5/02

(52) U.S. Cl. CPC H01L 21/67028; H01L 21/02041; H01L 21/68735; H01L 21/67173; B08B 5/02

(57) ABSTRACT

The present invention provides a substrate treating apparatus. The substrate treating apparatus includes a chamber configured to provide a space for processing a substrate, a support unit provided in the chamber and configured to support the substrate, and a nozzle configured to supply a cleaning medium to the substrate supported by the support unit, the nozzle may include a contraction part which has an inlet, through which the cleaning medium is introduced, and a cross-sectional area of which decreases as it goes far from the inlet, an expansion part which has an ejection hole, through which the cleaning medium is ejected, and a cross-sectional area of which increases as it becomes closer to the ejection hole, and an orifice located between the contraction part and the expansion part, and the cleaning medium introduced into the contraction part is a single gas.

### TECHNICAL FIELD

The present invention relates to a nozzle, a substrate treating apparatus including the same, and a substrate treating method.

### BACKGROUND ART

Contaminants such as particles, organic contaminants, and metallic contaminants on a surface of a substrate greatly influence the characteristics and yield rate of a semiconductor device. Due to this, a cleaning process of removing various contaminants attached to a surface of a substrate is very important, and a process of cleaning a substrate is performed before and after unit processes for manufacturing a semiconductor.

FIG. 1 illustrates a general substrate treating apparatus for cleaning a substrate by using carbon dioxide. Gaseous carbon dioxide is injected into an introduction hole of a nozzle N together with a carrier gas, and solid particles are ejected from an ejection hole of the nozzle N. The carrier gas is compressed nitrogen gas of high purity or the like. The carrier gas is provided to eject carbon dioxide at a high speed and a high pressure that is sufficient to clean a substrate.

Meanwhile, conventionally, when a cleaning medium is injected from a cleaning medium supply source 12, a cleaning medium is cooled by using a heat exchanger 30 in advance. However, temperature control is not easy, and accordingly, the cleaning medium is frequently overcooled. Accordingly, the injected cleaning medium fails to maintain the gaseous state.

Further, separate facilities 22, 24, 50, and 60 and costs are necessary to inject the carrier gas together. Further, conventionally, a process chamber is maintained in a vacuum state to eject the cleaning medium at a high speed. However, a separate facility for maintaining the interior of the chamber in a vacuum state is necessary, and there is a problem in securing a space.

### DETAILED DESCRIPTION OF THE INVENTION

### Technical Problem

The present invention provides a nozzle that may efficiently clean a substrate while maintaining the interior of a process chamber at a normal pressure during a cleaning process, a substrate treating apparatus, and a substrate treating method.

The present invention also provides a nozzle that may clean a substrate with a simple facility structure during a cleaning process, a substrate treating apparatus, and a substrate treating method.

The aspect of the present invention is not limited thereto, and other unmentioned aspects of the present invention may be clearly appreciated by those skilled in the art from the following descriptions.

### Technical Solution

The present invention provides a substrate treating apparatus.

According to an embodiment of the present invention, the substrate treating apparatus may include a chamber configured to provide a space for processing a substrate, a support unit provided in the chamber and configured to support the substrate, and a nozzle configured to supply a cleaning medium to the substrate supported by the support unit, the nozzle may include a contraction part which has an inlet, through which the cleaning medium is introduced, and a cross-sectional area of which decreases as it goes far from the inlet, an expansion part which has an ejection hole, through which the cleaning medium is ejected, and a cross-sectional area of which increases as it becomes closer to the ejection hole, and an orifice located between the contraction part and the expansion part, and the cleaning medium introduced into the contraction part may be a single gas.

According to an embodiment of the present invention, an area of the ejection hole may be 4 to 14 times as large as a sectional area of a passage of the orifice, taken perpendicular to a lengthwise direction of the passage of the orifice.

According to an embodiment of the present invention, an area of the ejection hole may be 6 to 10 times as large as a sectional area of a passage of the orifice, taken perpendicular to a lengthwise direction of the passage of the orifice.

According to an embodiment of the present invention, a diameter of the orifice may be 0.24 mm to 0.6 mm, and a diameter of the ejection hole may be 0.9 mm to 3.0 mm.

According to an embodiment of the present invention, a diameter of the orifice may be 0.3 mm to 0.5 mm, and a diameter of the ejection hole may be 0.9 mm to 1.1 mm.

According to an embodiment of the present invention, an area of the orifice may be 0.05 mm² to 0.28 mm², and an area of the ejection hole may be 0.7 mm² to 7 mm².

According to an embodiment of the present invention, an area of the orifice may be 0.10 mm² to 0.14 mm², and an area of the ejection hole may be 0.7 mm² to 1.4 mm².

According to an embodiment of the present invention, a vertical distance between the ejection hole and a surface of the substrate may be 2 cm to 5 cm.

According to an embodiment of the present invention, a vertical distance between the ejection hole and a surface of the substrate may be 2.5 cm to 4 cm.

According to an embodiment of the present invention, the ejection hole may be inclined with respect to a surface of the substrate.

According to an embodiment of the present invention, an inclination angle between the ejection hole and the surface of the substrate may be 25 degrees to 90 degrees.

According to an embodiment of the present invention, an inclination angle between the ejection hole and the surface of the substrate may be 25 degrees to 35 degrees.

According to an embodiment of the present invention, the cleaning medium may be carbon dioxide.

According to an embodiment of the present invention, an internal pressure of the chamber may be 0.01 bar to 1 bar, and a supply pressure of the cleaning medium introduced into the contraction part may be 20 bar to 60 bar.

According to an embodiment of the present invention, an internal pressure of the chamber may be 0.75 bar to 1.25 bar, and a supply pressure of the cleaning medium introduced into the contraction part may be 45 bar to 55 bar.

According to an embodiment of the present invention, an area of the ejection hole may be 4 to 14 times as large as a sectional area of a passage of the orifice, taken perpendicular to a lengthwise direction of the passage of the orifice, a vertical distance between the ejection hole and a surface of the substrate may be 2 cm to 5 cm, wherein the cleaning medium may be carbon dioxide, and an internal pressure of the chamber may be 0.01 bar to 1.25 bar, and a supply pressure of the cleaning medium introduced into the contraction part may be 20 bar to 60 bar.

According to an embodiment of the present invention, an area of the ejection hole may be 6 to 10 times as large as a sectional area of a passage of the orifice, taken perpendicular to a lengthwise direction of the passage of the orifice, a vertical distance between the ejection hole and a surface of the substrate may be 2.5 cm to 4 cm, the cleaning medium may be carbon dioxide, and an internal pressure of the chamber may be 0.75 bar to 1.25 bar, and a supply pressure of the cleaning medium introduced into the contraction part may be 45 bar to 55 bar.

According to an embodiment of the present invention, the ejection hole may be inclined with respect to a surface of the substrate, and an inclination angle between the ejection hole and the surface of the substrate is 25 degrees to 90 degrees.

According to an embodiment of the present invention, the ejection hole may be inclined with respect to a surface of the substrate, and an inclination angle between the ejection hole and the surface of the substrate may be 25 degrees to 35 degrees.

The present invention provides a nozzle for supplying a cleaning medium to a substrate.

According to an embodiment of the present invention, the nozzle may include a contraction part which has an inlet, through which the cleaning medium is introduced, and a cross-sectional area of which decreases as it goes far from the inlet, an expansion part which has an ejection hole, through which the cleaning medium is ejected, and a cross-sectional area of which increases as it becomes closer to the ejection hole, and an orifice located between the contraction part and the expansion part, and the cleaning medium introduced into the contraction part may be a single gas.

According to an embodiment of the present invention, an area of the ejection hole may be 4 to 14 times as large as a sectional area of a passage of the orifice, taken perpendicular to a lengthwise direction of the passage of the orifice.

According to an embodiment of the present invention, an area of the ejection hole may be 6 to 10 times as large as a sectional area of a passage of the orifice, taken perpendicular to a lengthwise direction of the passage of the orifice.

According to an embodiment of the present invention, a diameter of the orifice may be 0.24 mm to 0.6 mm, and a diameter of the ejection hole may be 0.9 mm to 3.0 mm.

According to an embodiment of the present invention, a diameter of the orifice may be 0.3 mm to 0.5 mm, and a diameter of the ejection hole may be 0.9 mm to 1.1 mm.

According to an embodiment of the present invention, an area of the orifice may be 0.05 mm² to 0.28 mm², and a diameter of the ejection hole may be 0.7 mm² to 7 mm².

According to an embodiment of the present invention, an area of the orifice may be 0.10 mm² to 0.14 mm², and an area of the ejection hole may be 0.7 mm² to 1.4 mm².

According to an embodiment of the present invention, the cleaning medium may be carbon dioxide.

The present invention provides a method for treating a substrate.

According to an embodiment of the present invention, the method may include supplying a single gaseous cleaning medium to an inlet of a nozzle, in which a contraction part, which has the inlet through which the cleaning medium is introduced, and a sectional area of which decreases as it goes far from the inlet, an orifice, and an expansion part, which has an ejection hole from which the cleaning medium is ejected and a sectional area of which increases as it becomes closer to the ejection hole are sequentially provided, and treating a substrate by ejecting the cleaning medium through the ejection hole of the nozzle, and the cleaning medium may be solidified by adiabatic expansion while passing through the orifice located between the inlet and the ejection hole.

According to an embodiment of the present invention, a vertical distance between the ejection hole and a surface of the substrate may be 2 cm to 5 cm.

According to an embodiment of the present invention, a vertical distance between the ejection hole and a surface of the substrate may be 2.5 cm to 4 cm.

According to an embodiment of the present invention, the cleaning medium may be obliquely ejected by providing the ejection hole such that the ejection hole is inclined with respect to a surface of the substrate.

According to an embodiment of the present invention, an inclination angle between the ejection hole and the surface of the substrate may be 25 degrees to 90 degrees.

According to an embodiment of the present invention, an inclination angle between the ejection hole and the surface of the substrate may be 25 degrees to 35 degrees.

According to an embodiment of the present invention, the treatment liquid may be carbon dioxide.

According to an embodiment of the present invention, an internal pressure of the chamber may be 0.01 bar to 1 bar.

According to an embodiment of the present invention, an internal pressure of the chamber may be 0.75 bar to 1.25 bar.

According to an embodiment of the present invention, an internal pressure of the chamber may be 20 bar to 60 bar.

According to an embodiment of the present invention, an internal pressure of the chamber may be 45 bar to 55 bar.

According to an embodiment of the present invention, an internal pressure of the chamber may be 0.01 bar to 1 bar, a supply pressure of the cleaning medium introduced into the contraction part may be 20 bar to 60 bar, and a vertical distance between the ejection hole and a surface of the substrate may be 2 cm to 5 cm.

According to an embodiment of the present invention, an internal pressure of the chamber may be 0.75 bar to 1.25 bar, and a supply pressure of the cleaning medium introduced into the contraction part may be 45 bar to 55 bar, and a vertical distance between the ejection hole and a surface of the substrate may be 2 cm to 5 cm.

According to an embodiment of the present invention, the cleaning medium may be obliquely ejected by providing the ejection hole such that the ejection hole is inclined with respect to a surface of the substrate, and an inclination angle between the ejection hole and the surface of the substrate may be 25 degrees to 90 degrees.

According to an embodiment of the present invention, the cleaning medium may be obliquely ejected by providing the ejection hole such that the ejection hole is inclined with respect to a surface of the substrate, and an inclination angle between the ejection hole and the surface of the substrate may be 25 degrees to 35 degrees.

### Advantageous Effects of the Invention

According to an embodiment of the present invention, the substrate may be efficiently cleaned while the interior of the process chamber is maintained at a normal pressure during a cleaning process.

According to an embodiment of the present invention, the substrate may be effectively cleaned by injecting a single gas during a cleaning process.

### DESCRIPTION OF THE DRAWINGS

FIG. 1 is a view schematically illustrating a conventional substrate treating apparatus for cleaning a substrate by using a cleaning medium;

FIG. 2 is a plan view schematically illustrating a substrate treating system according to the present invention;

FIG. 3 is a view illustrating a substrate treating apparatus for cleaning a substrate according to the present invention;

FIG. 4 is a view illustrating a nozzle according to the present invention;

FIG. 5 illustrates pictures depicting a cleaning degree according to a ratio between areas of an orifice and an ejection hole;

FIG. 6 illustrates pictures depicting a cleaning degree of a substrate according to an internal pressure of a chamber;

FIG. 7 is a view illustrating a relative location of a nozzle and a substrate in a substrate treating apparatus according to an example of the present invention;

FIG. 8 is a picture depicting a cleaning degree of a substrate according to a distance between the nozzle and the substrate in the substrate treating apparatus of FIG. 7;

FIG. 9 is a graph depicting a particle removal efficiency of a substrate according to a distance between the nozzle and the substrate in the substrate treating apparatus;

FIG. 10 is a view illustrating a relative location of a nozzle and a substrate in a substrate treating apparatus according to another example of the present invention;

FIG. 11 is a picture depicting a cleaning degree of a substrate according to an angle between the nozzle and the substrate in the substrate treating apparatus of FIG. 10;

FIG. 12 is a graph depicting a particle removal efficiency of a substrate according to an angle between the nozzle and the substrate in the substrate treating apparatus of FIG. 10;

FIG. 13 is a picture depicting a cleaning degree of a substrate according to a distance between the nozzle and the substrate and an angle between the nozzle and the substrate in the substrate treating apparatus of FIG. 10; and

FIG. 14 is a picture depicting a damage degree of a pattern of a substrate according to an angle between the nozzle and the substrate in the substrate treating apparatus of FIG. 10.

### BEST MODE

Hereinafter, exemplary embodiments of the present invention will be described in more detail with reference to the accompanying drawings. The embodiments of the present invention may be modified in various forms, and the scope of the present invention should not be construed to be limited to the following embodiments. The embodiments of the present invention are provided to describe the present invention for those skilled in the art more completely. Accordingly, the shapes of the components of the drawings are exaggerated to emphasize clearer description thereof.

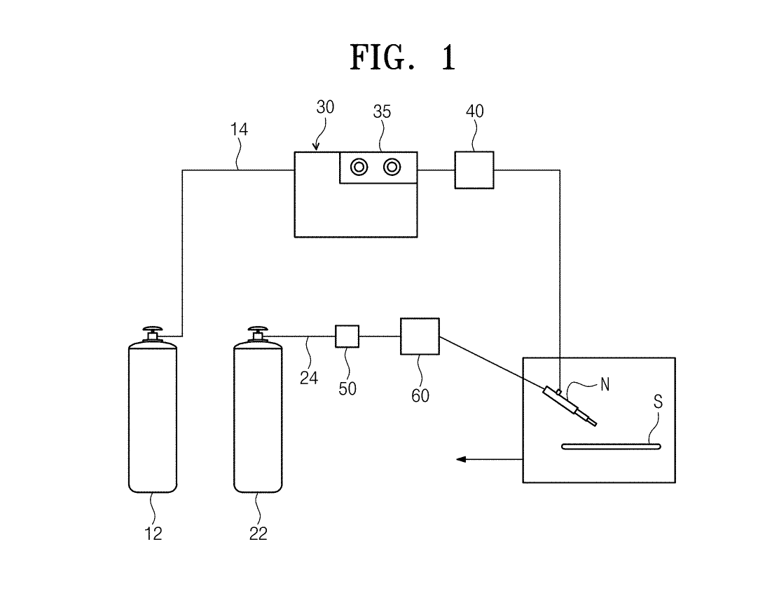

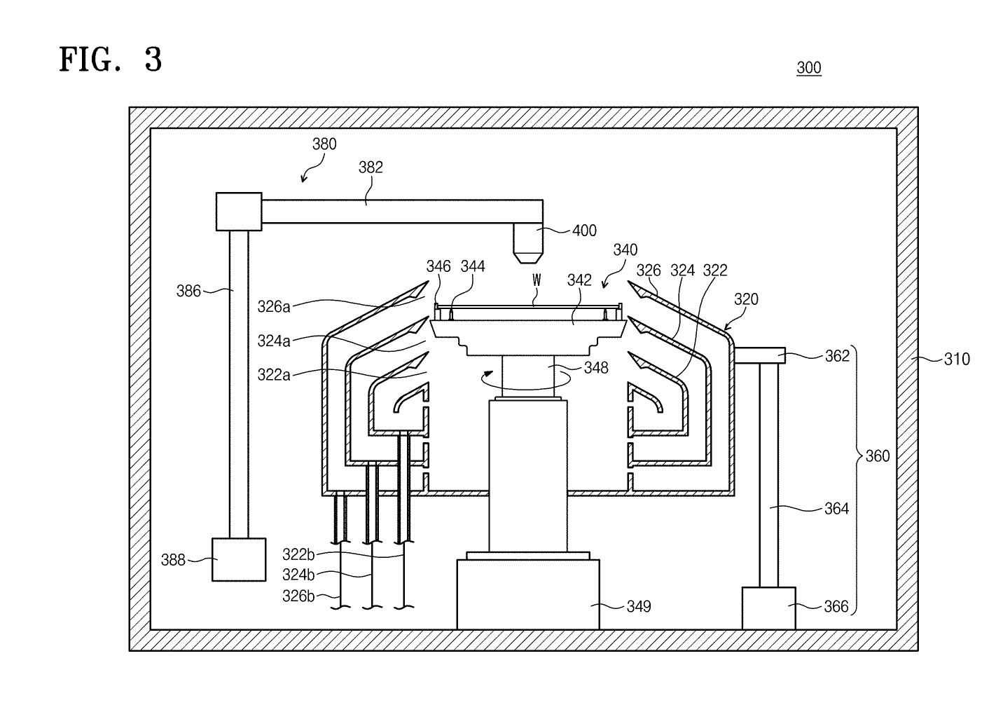

Hereinafter, exemplary embodiments of the present invention will be described with reference to FIGS. 1 to 14.

FIG. 1 is a plan view schematically illustrating a substrate treating system 1.

Referring to FIG. 1, the substrate treating system 1 includes an index module 100 and a process executing module 200. The index module 100 includes a plurality of load ports 120 and a feeding frame 140. The load port 120, the feeding frame 140, and the process treating module 200 may be sequentially arranged in a row. Hereinafter, a direction in which the load port 120, the feeding frame 140, and the process treating module 200 will be referred to a first direction 12. A direction perpendicular to the first direction 12 when viewed from the top will be referred to as a second direction 14, and a direction normal to a plane including the first direction 12 and the second direction 14 will be referred to as a third direction 16.

A carrier 130, in which a substrate W is received, is seated on the load port 120. A plurality of load ports 120 are provided, and are disposed along the second direction 14 in a row. FIG. 1 illustrates that four load ports 120 are provided. However, the number of the load ports 120 may increase or decrease according to a condition, such as the process efficiency of the process treating module 200 or a footprint. A plurality of slots (not illustrated) provided to support peripheries of substrates W are formed in the carrier 130. A plurality of slots are provided in the third direction 16. The substrates W are stacked in the carrier 130 while being spaced apart from each other along the third direction 16. A front opening unified pod (FOUP) may be used as the carrier 130.

The process executing module 200 includes a buffer unit 220, a feeding chamber 240, and a plurality of process chambers 260. The feeding chamber 240 is disposed such that the lengthwise direction thereof is in parallel to the first direction 12. The process chambers 260 are disposed on opposite sides of the feeding chamber 240 along the second direction 14. The process chambers 260 situated on one side of the feeding chamber 240 and the process chambers 260 situated on an opposite side of the feeding chamber 240 are symmetrical to each other with respect to the feeding chamber 240. Some of the process chambers 260 are disposed along the lengthwise direction of the feeding chamber 240. Furthermore, some of the process chambers 260 are disposed to be stacked on each other. That is, the process chambers 260 having an array of A by B (A and B are natural numbers) may be disposed on one side of the feeding chamber 240. Here, A is the number of the process chambers 260 provided in a row along the first direction 12, and B is the number of the process chambers 260 provided in a row along the third direction 16. When four or six process chambers 260 are provided on one side of the feeding chamber 240, the process chambers 260 may be disposed in an array of 2 by 2 or 3 by 2. The number of the process chambers 260 may increase or decrease. Unlike the above-mentioned description, the process chambers 260 may be provided only on one side of the feeding chamber 240. Further, unlike the above-mentioned description, the process chambers 260 may be provided on one side or opposite sides of the feeding chamber 240 to form a single layer.

A buffer unit 220 is disposed between the feeding frame 140 and the feeding chamber 240. The buffer unit 220 provides a space in which the substrates W stay before being transported, between the feeding chamber 240 and the feeding frame 140. Slots (not illustrated) in which the substrates W are positioned are provided in the buffer unit 220, and a plurality of slots (not illustrated) are provided to be spaced apart from each other along the third direction 16. Faces of the buffer unit 220 that faces the feeding frame 140 and faces the feeding chamber 240 are opened.

The feeding frame 140 transports the substrates W between the carrier 130 seated on the load port 120 and the buffer unit 220. An index rail 142 and an index robot 144 are provided in the feeding frame 140. The index rail 142 is provided such that the lengthwise direction thereof is in parallel to the second direction 14. The index robot 144 is installed on the index rail 142, and is linearly moved in the second direction 14 along the index rail 142. The index robot 144 has a base 144a, a body 144b, and a plurality of index arms 144c. The base 144a is installed to be moved along the index rail 142. The body 144b is coupled to the base 144a. The body 144b is provided to be moved along the third direction 16 on the base 144a. The body 144b is provided to be rotated on the base 144a. The index arms 144c are coupled to the body 144b, and are provided to be moved forwards and rearwards with respect to the body 144b. A plurality of index arms 144c are provided to be driven individually. The index arms 144c are disposed to be stacked so as to be spaced apart from each other along the third direction 16. Some of the index arms 144c are used when the substrates W are transported from the process executing module 200 to the carrier 130, and some of the index arms 155 may be used when the substrates W are transported from the carrier 130 to the process executing module 200. This structure may prevent particles generated from the substrates W before the process treatment from being attached to the substrates W after the process treatment in the process of carrying the substrates Win and out by the index robot 144.

The feeding chamber 240 transports the substrates W between the buffer unit 220 and the process chambers 260, and between the process chambers 260. A guide rail 242 and a main robot 244 are provided in the feeding chamber 240. The guide rail 242 is disposed such that the lengthwise direction thereof is in parallel to the first direction 12. The main robot 244 is installed on the guide rail 242, and is linearly moved along the first direction 12 on the guide rail 242. The main robot 244 has a base 244a, a body 244b, and a plurality of main arms 244c. The base 244a is installed to be moved along the guide rail 242. The body 244b is coupled to the base 244a. The body 244b is provided to be moved along the third direction 16 on the base 244a. The body 244b is provided to be rotated on the base 244a. The main arms 244c are coupled to the body 244b, and are provided to be moved forwards and rearwards with respect to the body 244b. A plurality of main arms 244c are provided to be driven individually. The main arms 244c are disposed to be stacked so as to be spaced apart from each other along the third direction 16. The main arms 244c used when the substrates W are transported from the buffer unit 220 to the process chambers 260 and the main arms 244c used when the substrates W are transported from the process chambers 260 to the buffer unit 220 may be different.

Substrate treating apparatuses 300 that perform cleaning processes on the substrates W are provided in the process chambers 260. The substrate treating apparatuses 300 provided in the process chambers 260 may have different structures according to the types of performed cleaning processes. Selectively, the substrate treating apparatuses 300 in the process chambers 260 may have the same structure. Selectively, the process chambers 260 may be classified into a plurality of groups such that the substrate treating apparatuses 300 provided in the process chambers 260 pertaining to the same group have the same structure and the substrate treating apparatuses 300 provided in the process chambers 260 pertaining to different groups have different structures. For example, when the process chambers 260 are classified into two groups, the first group of process chambers 260 may be provided on one side of the feeding chamber 240 and the second group of process chambers 260 may be provided on an opposite side of the feeding chamber 240. Selectively, the first group of process chambers 260 may be provided on the lower side of the feeding chamber 240 and the second group of process chambers 260 may be provided on the upper side of the feeding chamber 240, on opposite sides of the feeding chamber 240. The first group of process chambers 260 and the second group of process chambers 260 may be classified according to the kinds of the used chemicals or the types of cleaning methods.

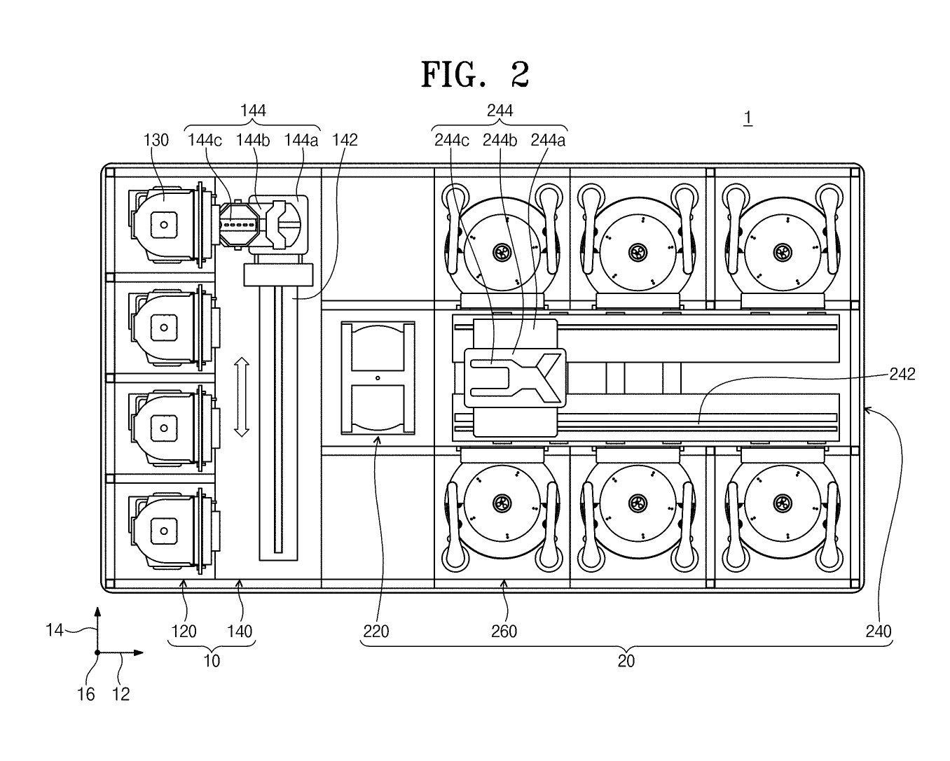

Hereinafter, an example of a substrate treating apparatus 300 that treats a substrate W will be described. FIG. 2 is a schematic view illustrating an example of the substrate treating apparatus 300.

Referring to FIG. 2, the substrate treating apparatus 300 includes a chamber 310, a cup 320, a support unit 340, an elevation unit 360, and an ejection unit 380.

The chamber 310 provides a space in the interior thereof. The internal pressure of the chamber 310 may be maintained at 0.01 bar to 1 bar. Further, the internal pressure of the chamber 310 may be maintained at 0.75 bar to 1.25 bar. For example, the internal pressure of the chamber 310 may be a normal pressure.

The cup 320 is located in a space in the chamber 310. The cup 320 has a space for performing a substrate treating process, and an upper side of the cup 320 is opened. The cup 320 has an inner recovery vessel 322, an intermediate recovery vessel 324, and an outer recovery vessel 326. The recovery vessels 322, 324, and 326 recover different treatment fluids used in the process. The inner recovery vessel 322 has an annular ring shape that surrounds the support unit 340, the intermediate recovery vessel 324 has an annular ring shape that surrounds the inner recovery vessel 322, and the outer recovery vessel has an annular ring shape that surrounds the intermediate recovery vessel 324. An inner space 322a of the inner recovery vessel 322, a space 324a between the inner recovery vessel 322 and the intermediate recovery vessel 324, and a space 326a between the intermediate recovery vessel 324 and the outer recovery vessel 326 function as inlets 410 through which the treatment fluids are introduced into the inner recovery vessel 322, the intermediate recovery vessel 324, and the outer recovery vessel 326. Recovery lines 322b, 324b, and 326b extending from the recovery vessels 322, 324, and 326 perpendicularly in the downward direction of the bottom surfaces thereof are connected to the recovery vessels 322, 324, and 326, respectively. The recovery lines 322b, 324b, and 326b discharge the treatment fluids introduced through the recovery vessels 322, 324, 326, respectively. The discharged treatment fluids may be reused through an external treatment fluid recycling system (not illustrated).

The support unit 340 is arranged in a treatment space of the cup 320. The support unit 340 supports and rotates the substrate during the process. The support unit 340 has a spin head 342, a plurality of support pins 344, a plurality of chuck pins 346, a drive shaft 348, and a driving unit 349. The spin head 342 has an upper surface having a substantially circular shape when viewed from the top. The drive shaft 348 that may be rotated by a driving unit 349 is fixedly coupled to the bottom of the spin head 342. If the driving shaft 348 is rotated, the spin head 342 is rotated. The spin head 342 includes a support pin 344 and a chuck pin 346 to support the substrate. A plurality of support pins 344 are provided. The support pins 344 may be arranged to be spaced apart from each other at a periphery of the upper surface of the spin head 342 and protrude upwards from the spin head 342. The support pins 344 are arranged to have a generally annular ring shape through combination thereof. The support pins 344 support a periphery of a bottom surface of the substrate such that the substrate W is spaced apart from the upper surface of the spin head 342 by a predetermined distance. A plurality of chuck pins 346 are provided. The chuck pins 346 are arranged to be more distant from the center of the spin head 342 than the support pins 344. The chuck pins 346 are provided to protrude upwards from the spin head 342. The chuck pins 346 support a side surface of the substrate such that the substrate is not separated laterally from a proper place when the support unit 340 is rotated. The chuck pins 346 are provided to be linearly moved between a standby position and a support position along a radial direction of the spin head 342. The standby position is a position that is more distant from the center of the spin head 342 than the support position. When the substrate is loaded on or unloaded from the support unit 340, the chuck pins 346 are located at the standby position, and when a process is performed on the substrate, the chuck pins 346 are located at the support position. The chuck pins 346 are in contact with the side of the substrate at the support position.

The elevation unit 360 linearly moves the cup 320 upwards and downwards. The elevation unit 360 may move the plurality of recovery vessels 322, 324, and 326 of the cup 320. Although not illustrated, the recovery vessels may be individually moved. When the cup 320 is moved upwards and downwards, a relative height of the cup 320 to the support unit 340 is changed. The elevation unit 360 has a bracket 362, a movable shaft 364, and a driver 366. The bracket 362 is fixedly installed on an outer wall of the cup 320, and the movable shaft 364 that is moved upwards and downwards by the driver 366 is fixedly coupled to the bracket 362. The cup 320 is lowered such that, when the substrate W is positioned on the support unit 340 or is lifted from the support unit 340, the support unit 340 protrudes to the upper side of the cup 320. When the process is performed, the height of the cup 320 is adjusted such that the treatment fluid is introduced into the preset recovery vessel 360 according to the kind of the treatment fluid supplied to the substrate W. For example, the substrate is located at a height corresponding to an interior space 322a of the inner recovery vessel 322 while the substrate is treated by a first treatment fluid. Further, the substrate may be located at a height corresponding to a space 324a between the inner recovery vessel 322 and the intermediate recovery vessel 324 and a space 326a between the intermediate recovery vessel 324 and the outer recovery vessel 326 while the substrate is treated by a second treatment fluid and a third treatment fluid. Unlike those described above, the elevation unit 360 may move the support unit 340, instead of the cup 320, upwards and downwards. Further, unlike the above description, the cup 320 may have a single recovery vessel 322.

The ejection unit 380 ejects a cleaning medium onto the substrate W. The cleaning medium may be carbon dioxide. The cleaning medium may be chemicals. The chemicals may include a sulfuric acid. The chemicals may include a phosphoric acid. The cleaning medium may be a rinsing liquid. The rinsing liquid may be pure water. The ejection unit 380 may be rotated. One or a plurality of ejection units 380 may be provided. The ejection unit 380 has a nozzle support 382, a support 386, a driving unit 388, and a nozzle 400. The lengthwise direction of the support 386 is provided along the third direction 16, and the driving unit 388 is coupled to a lower end of the support 386. The driving unit 388 rotates and elevates the support 386. The nozzle support 382 is coupled to an end of the support 386, which is opposite to an end of the support 386 coupled to the driving unit 388, perpendicularly to the support 386. The nozzle 400 is installed on a bottom surface of an end of the nozzle support 382. The nozzle 400 is moved to a process location and a standby location by the driving unit 388. The process location is a location at which the nozzle 400 is arranged at a vertical upper portion of the cup 320, and the standby location is a location that deviates from the vertical upper portion of the cup 320.

FIG. 4 is a view schematically illustrating an inner structure of a nozzle according to the present invention.

The nozzle 400 has a contraction part 420, an expansion part 440, and an orifice 450. The contraction part 420, the orifice 450, and the expansion part 440 are sequentially provided. The contraction part 420 has an inlet 410. A cleaning medium is introduced through the inlet 410. The cross-section of the contraction part 420 decreases as it goes far away from the inlet 410. For example, the contraction part 420 may have a conical shape.

The cleaning medium introduced through the inlet 410 may be a single gas. The cleaning medium may be carbon dioxide. The supply pressure of the introduced cleaning medium may be 20 bar to 60 bar. The supply pressure of the cleaning medium may be 45 bar to 55 bar.

The expansion part 440 has an ejection hole 430. The ejection hole 430 ejects a cleaning medium. The cross-section of the expansion part 440 increases as it becomes closer to the ejection hole 430. For example, the expansion part 440 may have a conical shape. When being ejected from the ejection hole 430, the cleaning medium is ejected as solid particles.

The orifice 450 is located between the contraction part 420 and the expansion part 440. The orifice 450 may have a constant cross-sectional area along a lengthwise direction thereof.

The area of the ejection hole 430 may be 4 to 14 times as large as the cross-section of the orifice 450. The area of the ejection hole 430 may be 6 to 10 times as larger as the cross-section of the orifice 450.

That is, the area of the ejection hole 430 may be 4 to 14 times as large as the sectional area of the passage of the orifice 450, which is cut perpendicularly to a lengthwise direction of the orifice 450. Further, the area of the ejection hole 430 may be 6 to 10 times as large as the sectional area of the passage of the orifice 450.

According to an example, the diameter of the orifice 450 may be 0.24 mm to 0.6 mm, and the diameter of the ejection hole 430 may be 0.9 mm to 3.0 mm. Further, the diameter of the orifice may be 0.3 mm to 0.5 mm, and the diameter of the ejection hole may be 0.9 mm to 1.1 mm.

According to an example, the area of the orifice 450 may be 0.05 mm² to 0.28 mm², and the diameter of the ejection hole 430 may be 0.7 mm² to 7 mm². Further, the area of the orifice may be 0.10 mm² to 0.14 mm², and the area of the ejection hole may be 0.7 mm² to 1.4 mm².

Under the above-mentioned condition, the cleaning medium ejected from the ejection hole 430 may be ejected at a high speed and a high pressure such that the substrate may be sufficiently cleaned even without using a carrier gas. A particle removal efficiency of the substrate will be described with reference to an experimental result, which will be described below in relation to the above description.

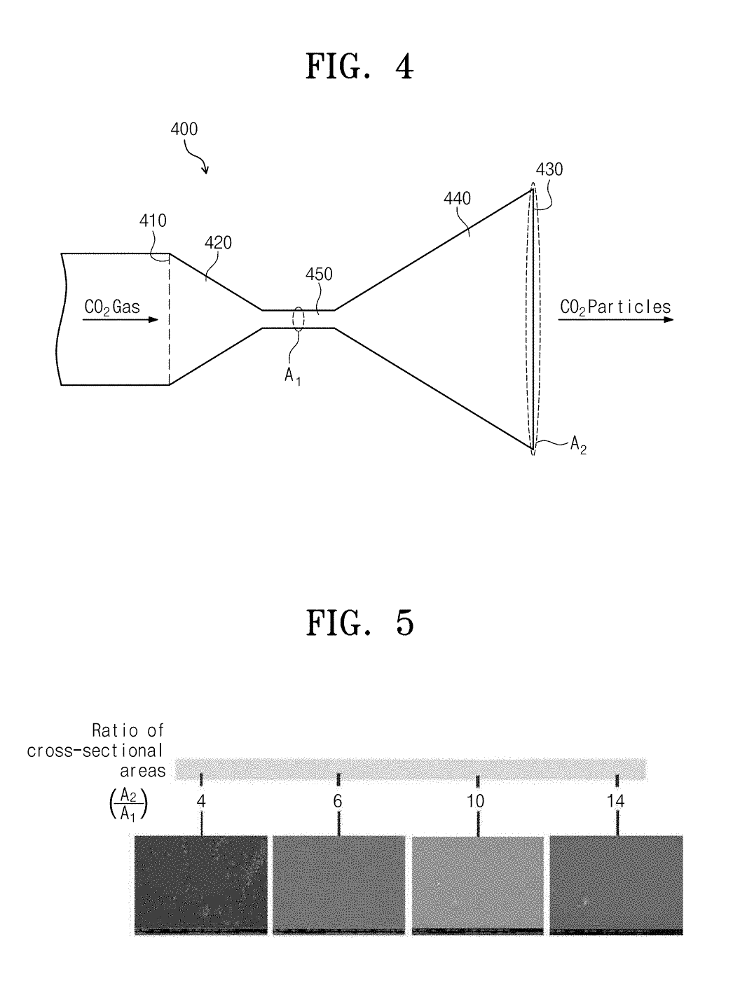

FIG. 5 illustrates pictures depicting a cleaning degree of the substrate according to a ratio of the areas of the orifice 450 and the ejection hole 430. Hereinafter, the relatively bright dots in the pictures are impurities residing after the cleaning. It means that as a larger amount of bright dots is distributed, the cleaning is more incomplete.

The following experiments were performed in a state in which the internal pressure of the chamber is not a vacuum pressure. Further, as a cleaning medium, only carbon dioxide in a single gaseous state was supplied without using a separate carrier gas.

It can be seen from FIG. 5 that the substrate may be cleaned only with a single carbon dioxide gas when the ratio of the cross-sectional area A1 of the orifice 450 and the area A2 of the ejection hole 430 is 4 to 14. In particular, when the ratio of the cross-sectional area A1 of the orifice 450 and the area A2 of the ejection hole 430 is 6 to 10, the impurities of the substrate are effectively cleaned.

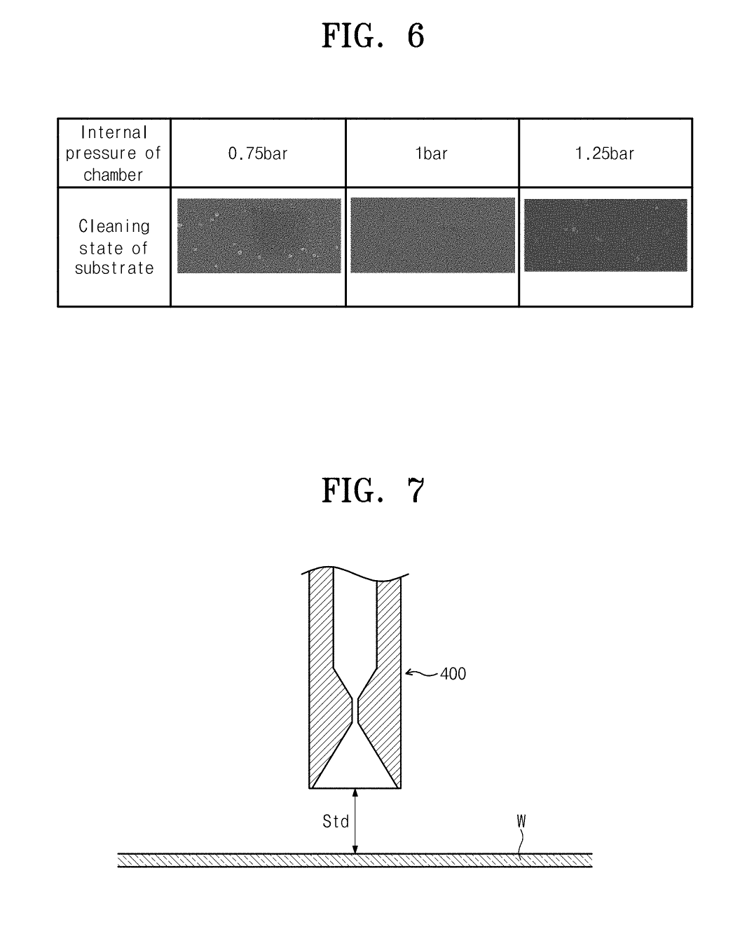

FIG. 6 illustrates pictures depicting a cleaning degree of a substrate according to an internal pressure of a chamber.

As described above, the nozzle 400, of which ratio of the cross-sectional area A1 of the orifice 450 and the area A2 of the ejection hole 430 is 6 to 10, was used, and the experiment was performed in a state in which the internal pressure of the chamber was not a vacuumed pressure. As an example, the experiments were performed when the internal pressures of the chamber is 0.75 bar, 1 bar, and 1.25 bar, respectively. The pressure at which the cleaning medium is supplied to the inlet 410 of the nozzle 400 was maintained at 45 bar to 55 bar. Referring to FIG. 6, it can be seen that the substrate was cleaned even when the internal pressure of the chamber is not a vacuumed pressure. In particular, the substrate was effectively cleaned at between 0.75 bar and 1.25 bar.

FIG. 7 is a view illustrating a relative location of a nozzle 400 and a substrate in a substrate treating apparatus according to an example of the present invention. Referring to FIG. 7, the ejection hole 430 of the nozzle 400 may eject a cleaning medium from a direction that is perpendicular to a surface of the substrate.

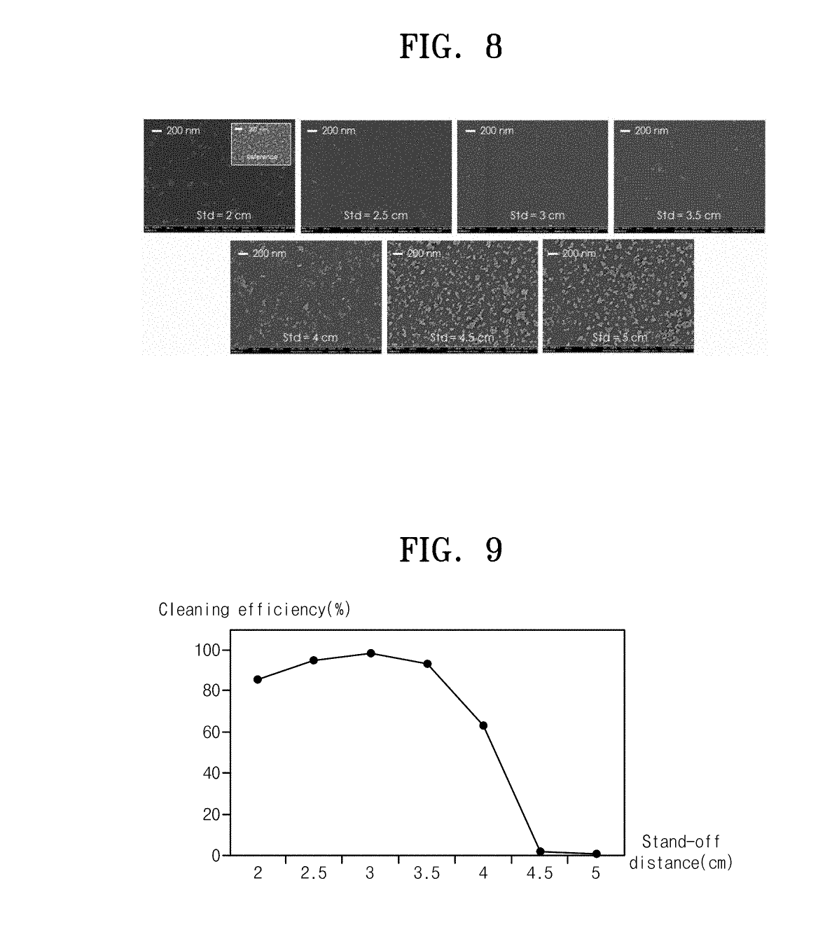

FIG. 8 is a picture depicting a cleaning degree of a substrate according to a distance between the nozzle 400 and the substrate in the substrate treating apparatus of FIG. 7. A cleaning degree of the substrate varies according to a stand-off distance (Std) between the ejection hole 430 and a surface of the substrate. The nozzle 400 is a nozzle 400, of which a ratio of a sectional area A1 of the orifice 450 to area A2 of the ejection hole 430 is 6 to 10. Further, the internal pressure of the chamber is maintained at a normal pressure. The pressure at which the cleaning medium is supplied to the inlet 410 of the nozzle 400 was maintained at 45 bar to 55 bar. In FIG. 8, a cleaning degree of the substrate after the process was photographed in unit of 0.5 cm in a stand-off distance range of 2 cm to 5 cm. Referring to FIG. 8, it may be seen that the substrate may be cleaned only with a single carbon dioxide gas in a stand-off distance (Std) range of 2 cm to 5 cm. In particular, it may be seen that the cleaning operation is effectively performed at the stand-off distance of 2.5 cm to 4 cm. When the stand-off distance is excessively small, for example, if the stand-off distance is less than 2 cm, the cleaning medium such as carbon dioxide fails to sufficiently grow to solid particles and accordingly, the particle removal efficiency deteriorates. When the stand-off distance is excessively large, for example, if the stand-off distance exceeds 4 cm, the cleaning medium of solid particles fails to reach the substrate, and accordingly, the particle removal efficiency of the substrate deteriorates.

FIG. 9 is a graph depicting a particle removal efficiency of a substrate according to a distance between the nozzle 400 and the substrate in the substrate treating apparatus. Referring to FIG. 9, it can be seen that the substrate is cleaned at the stand-off distance of 2 cm to 5 cm.

In particular, the particle removal efficiency is 98% to 99% in a stand-off distance range of 2.5 cm to 3.5 cm.

The particle removal efficiency (PRE) was calculated by comparing the number of contaminant particles existing on the substrate before the cleaning process and the number of contaminant particles residing after the cleaning process.

$$\frac{\begin{matrix}Number of contaminant particles before cleaning - \\ Number of contaminant particles after cleaning\end{matrix}}{Number of contaminant particles before cleaning} \times 100$$

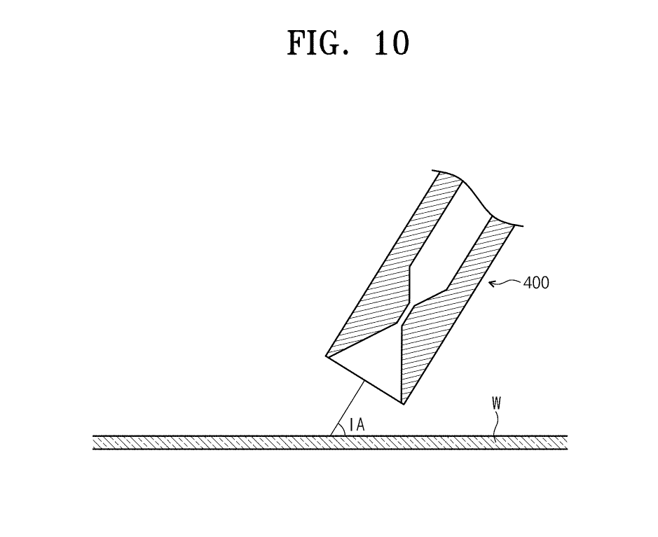

FIG. 10 is a view illustrating a relative location of a nozzle and a substrate in a substrate treating apparatus according to a second embodiment of the present invention.

Unlike the first embodiment, a cleaning medium from an ejection hole 430 may be ejected obliquely onto a surface of a substrate by inclining a nozzle 400 at a specific angle with respect to the surface of the substrate.

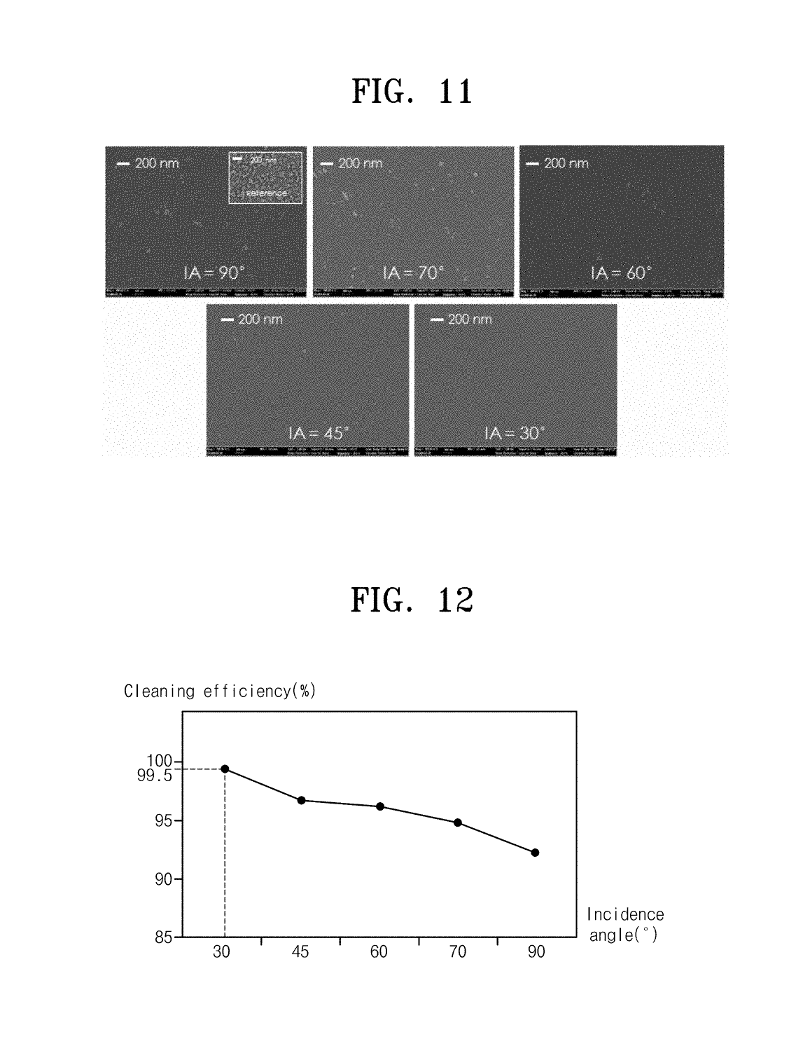

FIG. 11 is a picture depicting a cleaning degree of a substrate according to an angle between the nozzle 400 and the substrate in the substrate treating apparatus of FIG. 10.

Like the nozzle 400 of the first embodiment, the user nozzle 400 is a nozzle 400, of which a ratio of an area A1 of the ejection hole 430 to a sectional area A1 of the orifice 450 is 6 to 10. A pressure at which the cleaning medium is supplied into the nozzle 400 is maintained at 45 bar to 55 bar, and an internal pressure of the chamber is maintained at a normal pressure.

Referring to FIG. 11, it may be seen that when the internal pressure is a normal pressure and only a single carbon oxide gas is supplied, the substrate is cleaned even though the ejection hole 430 is inclined at a specific angle of not more than 90 degrees with respect to a surface of the substrate.

As an angle by which the ejection hole 430 is inclined with respect to a surface of the substrate, that is, an incidence angle (IA) becomes smaller from 90 degrees, the substrate may be efficiently cleaned. If the cleaning medium is obliquely ejected, a velocity component of the ejected cleaning medium is a combination of a horizontal component and a vertical component. As the horizontal component of the ejected cleaning medium becomes larger, the cleaning of the substrate becomes higher. Accordingly, as the incidence angle becomes smaller, the horizontal component become larger, and accordingly, the cleaning efficiency of the substrate may become higher.

FIG. 12 is a graph depicting a cleaning efficiency of a substrate according to an angle between the nozzle and a surface of the substrate in the substrate treating apparatus of FIG. 10. It may be seen that when the incidence angle (IA) is 30 degrees, the cleaning efficiency reaches 99.5%.

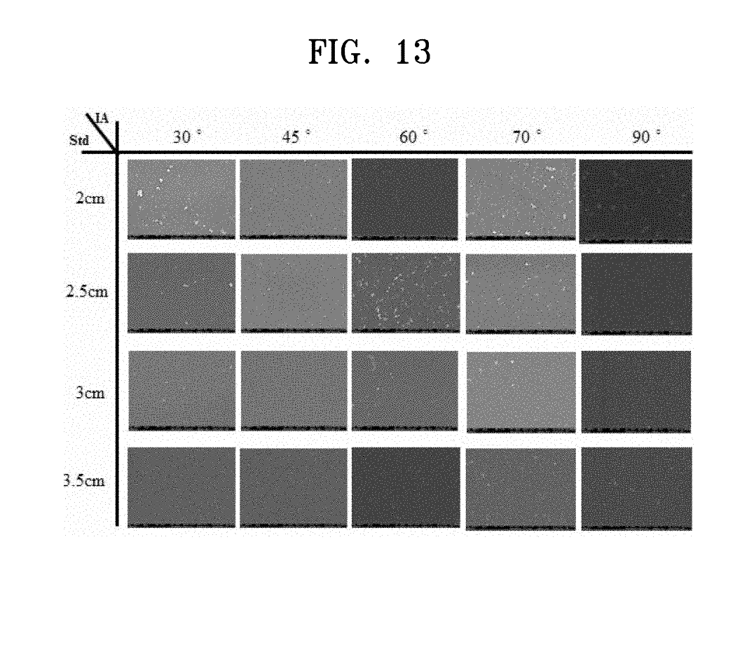

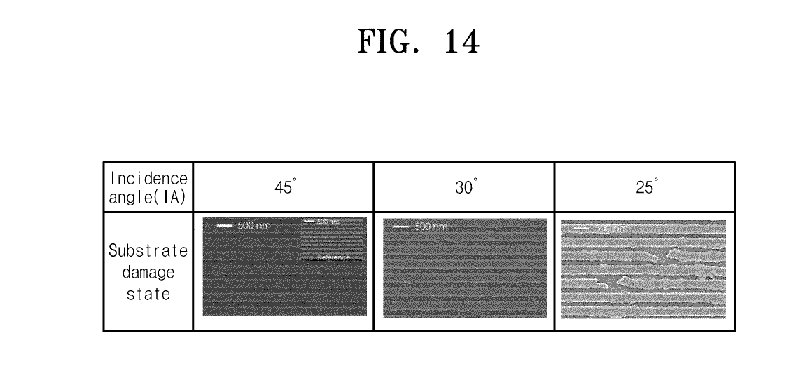

FIG. 13 is a picture depicting a cleaning degree of a substrate according to a distance between the nozzle and the substrate and an angle between the nozzle and the substrate in the substrate treating apparatus of FIG. 10. Referring to FIG. 13, when the stand-off distance was 2.5 cm to 4 cm and the incidence angle is 30 degrees, the substrate was efficiently performed.

FIG. 14 is a picture depicting a damage degree of a pattern of a substrate according to an angle between the nozzle and the substrate in the substrate treating apparatus of FIG. 10. As described above, the horizontal component of the velocity component of the ejected cleaning medium is the larger, the cleaning operation may be efficiently performed. Meanwhile, if the horizontal component becomes excessively large, the pattern of the substrate is damaged. Referring to FIG. 14, it can be seen that when the incidence angle is less than 30 degrees, for example, 25 degrees, the pattern of the substrate is seriously damaged. Meanwhile, when the incidence angle is 30 degrees or more, the pattern of the substrate is not damaged. Accordingly, the incidence angle may be made to 25 degrees to 35 degrees to increase the cleaning efficiency while not damaging the pattern of the substrate.

Hereinafter, a method for treating a substrate by using the aforementioned substrate treating apparatus will be described.

The internal pressure of the process chamber for treating a substrate is maintained in a range of 0.01 bar to 1 bar. Further, it may be maintained at 0.75 bar to 1.25 bar. The internal pressure of the process chamber may be 1 bar that is a normal pressure condition.

The cleaning medium for cleaning the substrate may be carbon dioxide. The introduced cleaning medium may be a single carbon dioxide gas.

The pressure of the cleaning medium supplied to the introduction hole 410 of the nozzle 400 is maintained at 20 bar to 60 bar. The supply pressure of the cleaning medium may be 45 bar to 55 bar. The supply pressure may be 50 bar.

The substrate is cleaned by using a nozzle in which the area A2 of the ejection hole 430 is 4 to 14 times as large as the sectional area A1 of the passage of the orifice taken perpendicularly with respect to the lengthwise direction. The area A2 of the ejection hole 430 is 6 to 10 times as large as the sectional area A1 of the passage of the orifice taken perpendicularly with respect to the lengthwise direction. When being ejected from the ejection hole 430 of the nozzle 400, carbon dioxide is ejected as solid particles.

The cleaning medium is ejected while a stand-off distance between the ejection hole 430 of the nozzle and a surface of the substrate is maintained at 2 cm to 5 cm. The stand-off distance may be 2.5 cm to 4 cm. The ejection hole 430 of the nozzle 400 and the surface of the substrate may be perpendicular to each other. Alternatively, the cleaning medium may be ejected while the ejection hole 430 of the nozzle 400 is inclined at a specific angle with respect to the surface of the substrate. The specific angle is an incidence angle at which the cleaning medium is ejected onto the surface of the substrate, and the cleaning medium may be ejected at 25 degrees to 90 degrees. The ejection angle may be 25 degrees to 35 degrees.

The above description exemplifies the present invention. Furthermore, the above-mentioned contents describe the exemplary embodiment of the present invention, and the present invention may be used in various other combinations, changes, and environments. That is, the present invention can be modified and corrected without departing from the scope of the present invention that is disclosed in the specification, the equivalent scope to the written disclosures, and/or the technical or knowledge range of those skilled in the art. The written embodiment describes the best state for implementing the technical spirit of the present invention, and various changes required in the detailed application fields and purposes of the present invention can be made. Accordingly, the detailed description of the present invention is not intended to restrict the present invention in the disclosed embodiment state. Furthermore, it should be construed that the attached claims include other embodiments.

1. A substrate treating apparatus comprising:
a chamber configured to provide a space for processing a substrate;
a support unit provided in the chamber and configured to support the substrate; and
a nozzle configured to supply a cleaning medium to the substrate supported by the support unit,
wherein the nozzle includes:
a contraction part which has an inlet, through which the cleaning medium is introduced, and a cross-sectional area of which decreases as it goes far from the inlet;
an expansion part which has an ejection hole, through which the cleaning medium is ejected, and a cross-sectional area of which increases as it becomes closer to the ejection hole; and
an orifice located between the contraction part and the expansion part, and
wherein the cleaning medium introduced into the contraction part is a single gas.

2. The substrate treating apparatus of claim 1, wherein an area of the ejection hole is 4 to 14 times as large as a cross-sectional area of a passage of the orifice.

3. The substrate treating apparatus of claim 1, wherein an area of the ejection hole is 6 to 10 times as large as a cross-sectional area of a passage of the orifice.

4. The substrate treating apparatus of claim 1, wherein a diameter of the orifice is 0.24 mm to 0.6 mm, and a diameter of the ejection hole is 0.9 mm to 3.0 mm.

5. The substrate treating apparatus of claim 1, wherein a diameter of the orifice is 0.3 mm to 0.5 mm, and a diameter of the ejection hole is 0.9 mm to 1.1 mm.

6. The substrate treating apparatus of claim 1, wherein an area of the orifice is 0.05 mm² to 0.28 mm², and an area of the ejection hole is 0.7 mm² to 7 mm².

7. The substrate treating apparatus of claim 1, wherein an area of the orifice is 0.10 mm² to 0.14 mm², and an area of the ejection hole is 0.7 mm² to 1.4 mm².

8. The substrate treating apparatus of claim 1, wherein a vertical distance between the ejection hole and a surface of the substrate is 2 cm to 5 cm.

9. The substrate treating apparatus of claim 1, wherein a vertical distance between the ejection hole and a surface of the substrate is 2.5 cm to 4 cm.

10. The substrate treating apparatus of claim 1, wherein the ejection hole is inclined with respect to a surface of the substrate.

11. The substrate treating apparatus of claim 10, wherein an inclination angle between the ejection hole and the surface of the substrate is 25 degrees to 90 degrees.

12. The substrate treating apparatus of claim 10, wherein an inclination angle between the ejection hole and the surface of the substrate is 25 degrees to 35 degrees.

13. The substrate support apparatus of claim 12, wherein the cleaning medium is carbon dioxide.

14. The substrate treating apparatus of claim 13, wherein an internal pressure of the chamber is 0.01 bar to 1 bar, and a supply pressure of the cleaning medium introduced into the contraction part is 20 bar to 60 bar.

15. The substrate treating apparatus of claim 13, wherein an internal pressure of the chamber is 0.75 bar to 1.25 bar, and a supply pressure of the cleaning medium introduced into the contraction part is 45 bar to 55 bar.

16. The substrate treating apparatus of claim 1, wherein an area of the ejection hole is 4 to 14 times as large as a cross-sectional area of a passage of the orifice,
wherein a vertical distance between the ejection hole and a surface of the substrate is 2 cm to 5 cm,
wherein the cleaning medium is carbon dioxide, and
wherein an internal pressure of the chamber is 0.01 bar to 1.25 bar, and a supply pressure of the cleaning medium introduced into the contraction part is 20 bar to 60 bar.

17. The substrate treating apparatus of claim 1, wherein an area of the ejection hole is 6 to 10 times as large as a cross-sectional area of a passage of the orifice,
wherein a vertical distance between the ejection hole and a surface of the substrate is 2.5 cm to 4 cm,
wherein the cleaning medium is carbon dioxide, and
wherein an internal pressure of the chamber is 0.75 bar to 1.25 bar, and a supply pressure of the cleaning medium introduced into the contraction part is 45 bar to 55 bar.

18. The substrate treating apparatus of claim 16, wherein the ejection hole is inclined with respect to a surface of the substrate, and
wherein an inclination angle between the ejection hole and the surface of the substrate is 25 degrees to 90 degrees.

19. The substrate treating apparatus of claim 16, wherein the ejection hole is inclined with respect to a surface of the substrate, and
wherein an inclination angle between the ejection hole and the surface of the substrate is 25 degrees to 35 degrees.

20. A nozzle for supplying a cleaning medium to a substrate, the nozzle comprising:
a contraction part which has an inlet, through which the cleaning medium is introduced, and a cross-sectional area of which decreases as it goes far from the inlet;
an expansion part which has an ejection hole, through which the cleaning medium is ejected, and a cross-sectional area of which increases as it becomes closer to the ejection hole; and
an orifice located between the contraction part and the expansion part,
wherein the cleaning medium introduced into the contraction part is a single gas.

21. The nozzle of claim 20, wherein an area of the ejection hole is 4 to 14 times as large as a cross-sectional area of a passage of the orifice/

22. The nozzle of claim 20, wherein an area of the ejection hole is 6 to 10 times as large as a cross-sectional area of a passage of the orifice.

23. The nozzle of claim 20, wherein a diameter of the orifice is 0.24 mm to 0.6 mm, and a diameter of the ejection hole is 0.9 mm to 3.0 mm.

24. The nozzle of claim 20, wherein a diameter of the orifice is 0.3 mm to 0.5 mm, and a diameter of the ejection hole is 0.9 mm to 1.1 mm.

25. The nozzle of claim 20, wherein an area of the orifice is 0.05 mm² to 0.28 mm², and a diameter of the ejection hole is 0.7 mm² to 7 mm².

26. The nozzle of claim 20, wherein an area of the orifice is 0.10 mm² to 0.14 mm², and an area of the ejection hole is 0.7 mm² to 1.4 mm².

27. The substrate cleaning apparatus of claim 26, wherein the cleaning medium is carbon dioxide.

28. A method for treating a substrate, comprising:
supplying a single gaseous cleaning medium to an inlet of a nozzle, in which a contraction part, which has the inlet through which the cleaning medium is introduced, and a cross-sectional area of which decreases as it goes far from the inlet, an orifice, and an expansion part, which has an ejection hole from which the cleaning medium is ejected and a cross-sectional area of which increases as it becomes closer to the ejection hole are sequentially provided; and
treating a substrate by ejecting the cleaning medium through the ejection hole of the nozzle, and
wherein the cleaning medium is solidified by adiabatic expansion while passing through the orifice located between the inlet and the ejection hole.

29. The substrate treating method of claim 28, wherein a vertical distance between the ejection hole and a surface of the substrate is 2 cm to 5 cm.

30. The substrate treating method of claim 28, wherein a vertical distance between the ejection hole and a surface of the substrate is 2.5 cm to 4 cm.

31. The substrate treating method of claim 28, wherein the cleaning medium is obliquely ejected by providing the ejection hole such that the ejection hole is inclined with respect to a surface of the substrate.

32. The substrate treating method of claim 31, wherein an inclination angle between the ejection hole and the surface of the substrate is 25 degrees to 90 degrees.

33. The substrate treating method of claim 31, wherein an inclination angle between the ejection hole and the surface of the substrate is 25 degrees to 35 degrees.

34. The substrate cleaning apparatus of claim 33, wherein the treatment liquid is carbon dioxide.

35. The substrate treating method of claim 34, wherein an internal pressure of a chamber is 0.01 bar to 1 bar, and a supply pressure of the cleaning medium introduced into the contraction part is 20 bar to 60 bar.

36. The substrate treating method of claim 34, wherein an internal pressure of a chamber is 0.75 bar to 1.25 bar, and a supply pressure of the cleaning medium introduced into the contraction part is 45 bar to 55 bar.

37. The substrate treating method of claim 28, wherein an internal pressure of a chamber is 0.01 bar to 1 bar,
wherein the cleaning medium is carbon dioxide, and
wherein a supply pressure of the cleaning medium introduced into the contraction part is 20 bar to 60 bar, and a vertical distance between the ejection hole and a surface of the substrate is 2 cm to 5 cm.

38. The substrate treating method of claim 28, wherein an internal pressure of a chamber is 0.75 bar to 1.25 bar,
wherein the cleaning medium is carbon dioxide, and
wherein a supply pressure of the cleaning medium introduced into the contraction part is 45 bar to 55 bar, and a vertical distance between the ejection hole and a surface of the substrate is 2.5 cm to 4 cm.

39. The substrate treating method of claim 37, wherein the cleaning medium is obliquely ejected by providing the ejection hole such that the ejection hole is inclined with respect to a surface of the substrate, and
wherein an inclination angle between the ejection hole and the surface of the substrate is 25 degrees to 90 degrees.

40. The substrate treating method of claim 37, wherein the cleaning medium is obliquely ejected by providing the ejection hole such that the ejection hole is inclined with respect to a surface of the substrate, and
wherein an inclination angle between the ejection hole and the surface of the substrate is 25 degrees to 35 degrees.
